(19) United States
(12) Patent Application Publication
(10) Pub. No.: US 2025/0194249 A1
(43) Pub. Date: Jun. 12, 2025

(54) ANGLED EPITAXY CUT

(71) Applicant: International Business Machines Corporation, Armonk, NY (US)

(72) Inventors: Ruilong Xie, Niskayuna, NY (US); Min Gyu Sung, Latham, NY (US); Julien Frougier, Albany, NY (US); Chanro Park, Clifton Park, NY (US); Juntao Li, Cohoes, NY (US)

(21) Appl. No.: 18/531,855

(22) Filed: Dec. 7, 2023

(51) Int. Cl. H01L 27/12

(52) U.S. Cl. CPC H10D 86/60; H10D 86/0214; H10D 86/441

(57) ABSTRACT

Embodiments of the present disclosure are directed to processing methods and resulting structures that leverage an angled epitaxy cut to provide an angled source/drain isolation pillar that optimizes contact size for both frontside contacts and backside contacts. In a non-limiting embodiment, a semiconductor device includes a first source or drain (S/D) region and a second S/D region. The semiconductor device further includes an angled isolation pillar between the first S/D region and the second S/D region.

### BACKGROUND

The present disclosure generally relates to fabrication methods and resulting structures for semiconductor devices, and more specifically, to processing methods and resulting structures for leveraging an angled epitaxy cut to provide angled source/drain isolation pillars.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively PPA, is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

### SUMMARY

Embodiments of the disclosure are directed to semiconductor devices having angled source/drain isolation pillars that optimize contact size for both frontside contacts and backside contacts. A non-limiting example of the semiconductor device includes a first source or drain (S/D) region and a second S/D region. The semiconductor device further includes an angled isolation pillar between the first S/D region and the second S/D region.

Embodiments of the disclosure are directed to a method for leveraging an angled epitaxy cut to provide an angled source/drain isolation pillar that optimizes contact size for both frontside contacts and backside contacts. A non-limiting example of the method includes forming a first S/D region and forming a second S/D region. The method further includes forming an angled isolation pillar between the first S/D region and the second S/D region.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1A depicts a top-down view of a semiconductor wafer after an initial set of processing operations according to one or more embodiments;

FIGS. 1B and 1C depict cross-sectional views taken along the lines X (across gate in channel region) and Y (across source/drain) in FIG. 1A, respectively, after the initial set of processing operations according to one or more embodiments;

FIGS. 2A and 2B depict cross-sectional views taken along the lines X and Y, respectively, after a processing operation according to one or more embodiments;

FIGS. 3A and 3B depict cross-sectional views taken along the lines X and Y, respectively, after a processing operation according to one or more embodiments;

FIGS. 4A and 4B depict cross-sectional views taken along the lines X and Y, respectively, after a processing operation according to one or more embodiments;

FIGS. 5A and 5B depict cross-sectional views taken along the lines X and Y, respectively, after a processing operation according to one or more embodiments;

FIGS. 6A and 6B depict cross-sectional views taken along the lines X and Y, respectively, after a processing operation according to one or more embodiments;

FIGS. 7A and 7B depict cross-sectional views taken along the lines X and Y, respectively, after a processing operation according to one or more embodiments;

FIGS. 8A and 8B depict cross-sectional views taken along the lines X and Y, respectively, after a processing operation according to one or more embodiments;

FIGS. 9A and 9B depict cross-sectional views taken along the lines X and Y, respectively, after a processing operation according to one or more embodiments;

FIGS. 10A and 10B depict cross-sectional views taken along the lines X and Y, respectively, after a processing operation according to one or more embodiments;

FIG. 11 depicts a cross-sectional view taken along the line Y after the processing operation of FIG. 10B according to one or more embodiments; and

FIG. 12 depicts a flow diagram illustrating a method according to one or more embodiments.

The diagrams depicted herein are illustrative. There can be many variations to the diagram or the operations described therein without departing from the spirit of this disclosure. For instance, the actions can be performed in a differing order or actions can be added, deleted or modified.

In the accompanying figures and following detailed description of the described embodiments of the disclosure, the various elements illustrated in the figures are provided with two or three-digit reference numbers. With minor exceptions, the leftmost digit(s) of each reference number correspond to the figure in which its element is first illustrated.

### DETAILED DESCRIPTION

According to an aspect of the disclosure, there is provided a semiconductor device. A non-limiting example of the semiconductor device includes a first source or drain (S/D) region and a second S/D region. The semiconductor device further includes an angled isolation pillar between the first S/D region and the second S/D region. Advantageously, the angled isolation pillar provides an optimized contact size for both frontside contacts and backside contacts.

In some embodiments, the semiconductor device includes a frontside contact on the second S/D region and a backside contact on the first S/D region. The frontside contact size is relatively greater than frontside contact sizes for semiconductor devices having vertical (straight) isolation pillars.

In some embodiments, a first frontside contact size at an interface between the second S/D region and the frontside contact is longer than a second frontside contact size over the first S/D region and opposite the backside contact, and a first backside contact size at an interface between the first S/D region and the backside contact is longer than a second backside contact size below the second S/D region and opposite the frontside contact. The result is a final device having improved transport effects between the respective source/drain and contact.

In some embodiments, the first S/D region is electrically coupled to a backside of the semiconductor device through the backside contact and the second S/D region is electrically coupled to a frontside of the semiconductor device through the frontside contact. In this manner, the relatively longer source/drain-to-contact interfaces resulting from the angled isolation pillar are active.

In some embodiments, the first S/D region is not electrically coupled to the a frontside of the semiconductor device and the second S/D region is not electrically coupled to a backside of the semiconductor device. In this manner, the relatively shorter source/drain-to-contact interfaces resulting from the angled isolation pillar are inactive.

In some embodiments, the semiconductor device further includes a nanosheet stack having one or more nanosheets in direct contact with the first S/D region and the second S/D region. The nanosheets provide a channel between the first S/D region and the second S/D region.

In some embodiments, a width of the backside contact is greater than a width of the one or more nanosheets. In this manner, an available processing window for forming the angled isolation pillar can be increased.

In some embodiments, the semiconductor device further includes a frontside interconnect on the frontside contact and a backside interconnect on the backside contact. The frontside interconnect and backside interconnect provide electrical continuity to other devices on the frontside and backside, respectively, of the semiconductor device.

According to an aspect of the disclosure, there is provided a method for leveraging an angled epitaxy cut to provide an angled source/drain isolation pillar. A non-limiting example method includes forming a first S/D region and forming a second S/D region. The method includes forming an angled isolation pillar between the first S/D region and the second S/D region. Advantageously, the angled isolation pillar provides an optimized contact size for both frontside contacts and backside contacts.

In some embodiments, the method includes forming a frontside contact on the second S/D region and forming a backside contact on the first S/D region. The frontside contact size is relatively greater than frontside contact sizes for semiconductor devices having vertical (straight) isolation pillars.

In some embodiments, a first frontside contact size at an interface between the second S/D region and the frontside contact is longer than a second frontside contact size over the first S/D region and opposite the backside contact, and a first backside contact size at an interface between the first S/D region and the backside contact is longer than a second backside contact size below the second S/D region and opposite the frontside contact. The result is a final device having improved transport effects between the respective source/drain and contact.

In some embodiments, the first S/D region is electrically coupled to a backside of the semiconductor device through the backside contact and the second S/D region is electrically coupled to a frontside of the semiconductor device through the frontside contact. In this manner, the relatively longer source/drain-to-contact interfaces resulting from the angled isolation pillar are active.

In some embodiments, the first S/D region is not electrically coupled to the a frontside of the semiconductor device and the second S/D region is not electrically coupled to a backside of the semiconductor device. In this manner, the relatively shorter source/drain-to-contact interfaces resulting from the angled isolation pillar are inactive.

In some embodiments, the method further includes forming a nanosheet stack having one or more nanosheets in direct contact with the first S/D region and the second S/D region. The nanosheets provide a channel between the first S/D region and the second S/D region.

In some embodiments, a width of the backside contact is greater than a width of the one or more nanosheets. In this manner, an available processing window for forming the angled isolation pillar can be increased.

In some embodiments, the method further includes forming a frontside interconnect on the frontside contact and forming a backside interconnect on the backside contact. The frontside interconnect and backside interconnect provide electrical continuity to other devices on the frontside and backside, respectively, of the semiconductor device.

In some embodiments, the method further includes forming a backside sacrificial region on the first S/D region and replacing the backside sacrificial region with the backside contact. In this manner, the backside contact can be built after the FEOL.

In some embodiments, the method further includes forming protective spacers on sidewalls of the one or more nanosheets and forming a frontside sacrificial region on the backside sacrificial region. The protective spacers shield the FEOL structures when forming the angled isolation pillar.

In some embodiments, the method further includes forming an angled cut in the frontside sacrificial region. In some embodiments, the method further includes forming the angled isolation pillar by filling a portion of the angled cut with dielectric material. In this manner, the angled isolation pillar ensures electrical isolation (that is, prevents shorts), between the first S/D region and the second S/D region.

It is understood in advance that although example embodiments of the disclosure are described in connection with a particular transistor architecture, embodiments of the disclosure are not limited to the particular transistor architectures or materials described in this specification. Rather, embodiments of the present disclosure are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

A key component of the BEOL structure is the power delivery network (PDN). The PDN of an integrated circuit is defined by the conductors and vias connected to the power supply (VDD) and ground (VSS) terminals of the chip. The PDN is responsible for delivering power to the individual devices in the front end. The integration of the PDN in the BEOL has become particularly challenging as device densities continue to scale. Backside power delivery, also referred to as a backside power delivery network (BSPDN), is a chip architecture that involves repositioning layers of the PDN from the top of the FEOL to the opposite side of the chip to free space on the front side for additional elements (e.g., more transistors). In other words, in a backside-style architecture the PDN layers are placed on the backside of the semiconductor substrate onto which the active devices have been built.

Some challenges remain, however, in effectively placing the various backside power rails and backside contacts (e.g., gate, source, and/or drain contacts) required to provide electrical continuity to the backside devices of these architectures. For example, the placement of a backside source/drain contact is natively restricted by the dielectric gate spacer footing (sometimes referred to as the gate spacer footing, or simply, the footing) that remains in the source/drain area following the gate-spacer breakthrough. This footing is an inadvertent remnant of the FEOL, as the source/drain epitaxy naturally shields the dielectric spacer from being fully removed. The footing reduces the available footprint for the backside source/drain contact and results in a limited interface between the backside source/drain contact and the source/drain epitaxy. In another, somewhat related example, as channel lengths and the space between adjacent channels (e.g., the channel-to-channel spacing) continues to shrink to accommodate smaller devices, source/drain isolation is becoming more difficult and there is a need for self-aligned isolation and/or epitaxy cuts to prevent source/drain shorts. One approach to source/drain isolation is a so-called epitaxy cut structure, which is a dielectric structure positioned between adjacent source/drain regions to ensure electrical isolation. Unfortunately, the epitaxy cut structure itself requires some device footprint and can further reduce the interface area between the backside (or frontside) contact and its respective source/drain region.

This disclosure introduces new fabrication methods and resulting structures that leverage an angled epitaxy cut to provide an angled source/drain isolation pillar that optimizes contact size for both frontside contacts and backside contacts. Rather than relying on a straight epitaxy cut, aspects of this disclosure instead cut the source/drain epitaxy at an angle that is selected such that the resultant angled source/drain isolation pillar offers a relatively longer frontside source/drain contact area where the frontside contact will land and a relatively longer backside source/drain contact area where the backside contact will land. In other words, the source/drain epitaxy is cut such that the top surface is longer than the bottom surface, or vice versa. The tradeoff of the angled source/drain isolation pillar is a pair of adjacent relatively shorter frontside and backside source/drain contact areas (e.g., at the neighboring device), but these occur where no contact is needed.

Leveraging angled epitaxy cuts and angled source/drain isolation pillars for source/drain isolation in accordance with one or more embodiments described herein offers various technical advantages over prior approaches. Notably, the contact area for both frontside and backside source/drain contacts can be increased at the same channel-to-channel spacing. This increased contact area in the source/drain regions results in a direct improvement in device performance. Other advantages are possible.

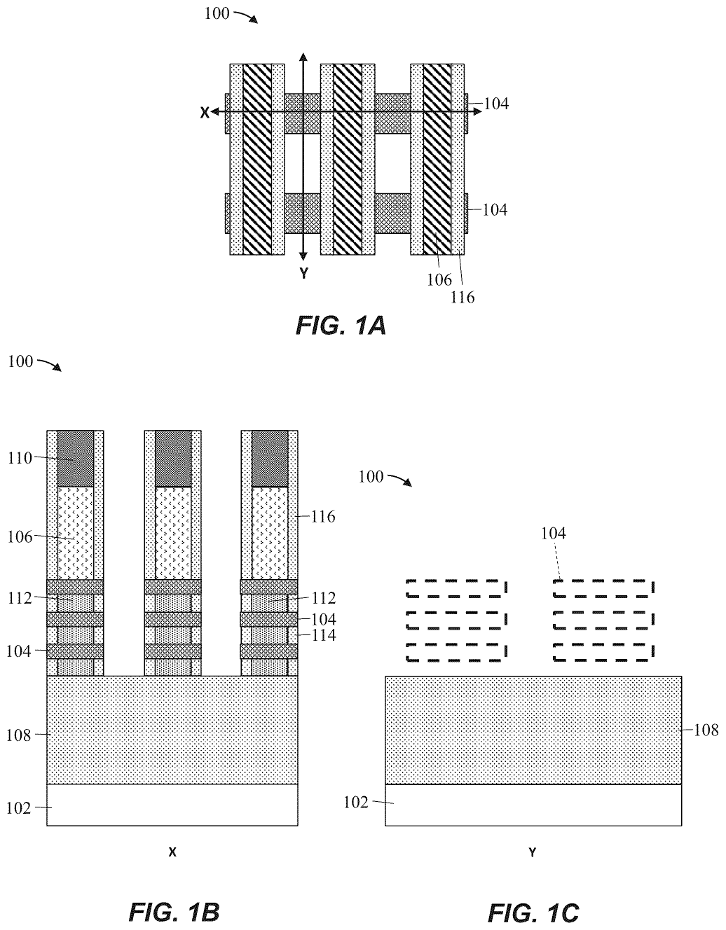

Turning now to a more detailed description of fabrication operations and resulting structures according to aspects of the disclosure, FIG. 1A depicts a top-down reference view of a semiconductor wafer 100 after an initial set of fabrication operations (e.g., various FEOL processes) have been applied as part of a method of fabricating a final semiconductor device according to one or more embodiments of the disclosure. FIG. 1B depicts a cross-sectional view taken along the line X (across gate in channel region) in FIG. 1A. FIG. 1C depicts a cross-sectional view taken along the line Y (across source/drain region) in FIG. 1A.

As shown in FIGS. 1A-1C, various FEOL structures have been built in the semiconductor wafer 100. The specific examples of the FEOL structures are illustrative only and are not meant to be particularly limited. For example, the semiconductor wafer 100 depicts a nanosheet-style transistor architecture. It should be understood, however, that the nanosheet-style transistor architecture is provided for ease of discussion only and that other transistor architectures (e.g., vertical tunneling transistors, planar transistors, finFETs, etc.) are included in the contemplated scope of this disclosure. Other FEOL structures can be fabricated depending on the needs of a given application, and all such configurations are within the contemplated scope of this disclosure.

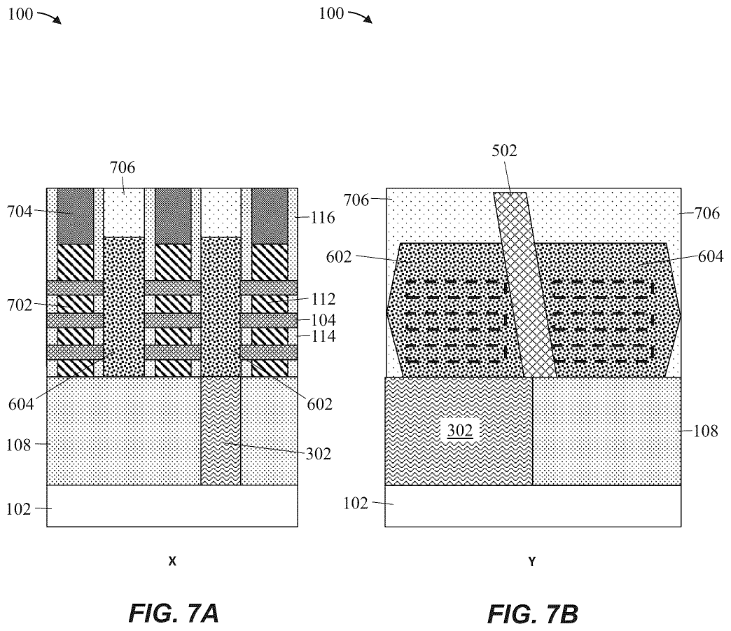

At the fabrication stage depicted in FIGS. 1B and 1C, known fabrication operations have been used to form a substrate 102, one or more nanosheets 104 (collectively, a nanosheet stack(s)) over the substrate 102, and a sacrificial gate 106 (sometimes referred to as a dummy gate) formed over channel regions of the one or more nanosheets 104. As used herein, a “channel region” refers to the portion of a nanosheet of the one or more nanosheets 104 over which a conductive gate is formed (refer to FIG. 7A), and through which current passes from source to drain in the final device. Note that, in FIG. 1C, the one or more nanosheets 104 are shown via projection only.

The substrate 102 and one or more nanosheets 104 can be made of any suitable semiconductor materials, such as, for example, monocrystal silicon, silicon germanium (SiGe), III-V compound semiconductor, II-VI compound semiconductor, and semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments, the substrate 102 is an incoming bulk substrate having a buried oxide layer 108. The buried oxide layer 108 can be made of any suitable dielectric oxide, such as, for example, silicon oxide.

The sacrificial gate 106 can be made of any suitable material, such as, for example, amorphous silicon or polysilicon. Any known method for patterning a sacrificial gate can be used, such as, for example, a wet etch, a dry etch, or a combination of sequential wet and/or dry etches. In some embodiments, the sacrificial gate 106 is patterned using a hard mask 110.

In some embodiments, the one or more nanosheets 104 alternate with a corresponding number of sacrificial layers 112 (that is, a number of sacrificial layers 112 as needed to place a sacrificial layer between each adjacent nanosheet, and a bottommost sacrificial layer below the first (bottommost) nanosheet). In some embodiments, the sacrificial layers 112 are made of a material selected to provide etch selectivity with respect to the one or more nanosheets 104. For example, in embodiments where the one or more nanosheets 104 are silicon nanosheets, the sacrificial layers 112 can be silicon germanium layers. In embodiments where the one or more nanosheets 104 are silicon germanium nanosheets, the sacrificial layers 112 can be silicon layers or silicon germanium layers having a germanium concentration that is greater than the germanium concentration in the one or more nanosheets 104. For example, if the one or more nanosheets 104 are silicon germanium nanosheets having a germanium concentration of 5 percent (sometimes referred to as SiGe5), the sacrificial layers 112 can be silicon germanium layers having a germanium concentration of 25 percent (SiGe25), although other germanium concentrations are within the contemplated scope of this disclosure.

The semiconductor wafer 100 can include various additional FEOL structures, such as, for example, inner spacers 114 and gate spacers 116. The inner spacers 114 and gate spacers 116 can be made from any suitable dielectric materials, such as, for example, a low-k dielectric, a nitride, silicon nitride, silicon oxide, SiON, SiC, SiOCN, SiBCN, etc.

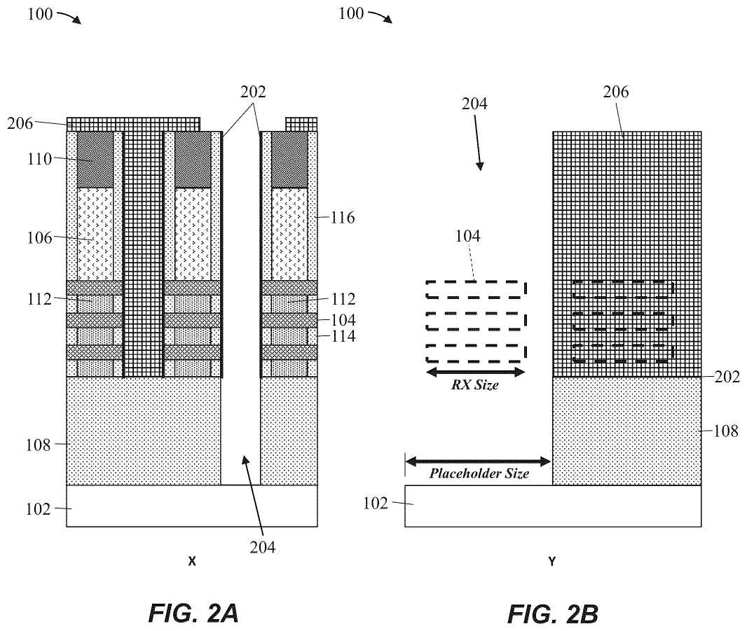

FIGS. 2A and 2B depict cross-sectional views of the semiconductor wafer 100 taken along the lines X and Y, respectively, after additional fabrication operations. As shown in FIGS. 2A and 2B, protective spacers 202 can be formed on the one or more nanosheets 104, the inner spacers 114, and the gate spacers 116. In some embodiments, the protective spacers 202 are made of a material selected to provide etch selectivity with respect to the buried oxide layer 108. In some embodiments, the protective spacers 202 are deposited as a continuous conformal layer that is patterned using a wet etch, a dry etch, or a combination of sequential wet and/or dry etches to remove portions of the conformal layer on the hard mask 110 and the buried oxide layer 108 (thus, arriving at the structure shown in FIG. 2A).

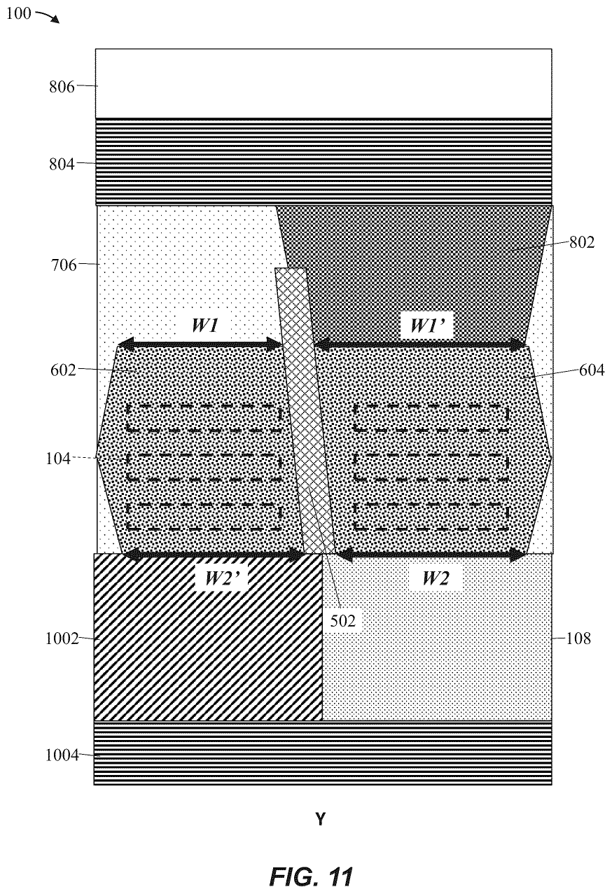

As further shown in FIGS. 2A and 2B, exposed portions of the buried oxide layer 108 are recessed to define a backside contact placeholder trench 204. This process can be referred to as backside contact patterning. Advantageously, the protective spacers 202 protect the other FEOL structures during this process. In some embodiments, the one or more nanosheets 104 have a first width (as shown, the “RX Size”) and the backside contact placeholder trench 204 is formed to a second width (as shown, the “Placeholder Size”) that is wider than the first width. Advantageously, forming the backside contact placeholder trench 204 results in a wider contact interface after metallization (refer to FIG. 11).

In some embodiments, a patterning film stack 206 is formed over the semiconductor wafer 100 and patterned (opened) to expose the buried oxide layer 108. The patterning film stack 206 can be a bi-layer stack, a tri-layer stack, or a multilayer stack including an organic planarization layer (OPL), an antireflective coating, and a photoresist layer (these layers are not separately shown). Patterning layer stacks typically include OPLs because high resolution photoresists themselves often do not provide enough etch resistance for pattern transfer. OPLs are used as etch masks for pattern transfers into inorganic substrates, to fill pre-existing features, and to planarize the substrate to allow for larger patterning process windows.

The OPL, if present, can be formed over a surface of the semiconductor wafer 100 using any suitable process. In some embodiments, the OPL can be applied using, for example, spin coating technology. In some embodiments, the OPL can include a photo-sensitive organic polymer having a light-sensitive material that, when exposed to electromagnetic (EM) radiation, is chemically altered and thus configured to be removed using a developing solvent. For example, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). More generally, for example, the OPL can include any organic polymer and a photo-active compound having a molecular structure that can attach to the molecular structure of the organic polymer. In some embodiments, the OPL material is selected to be compatible with the overlying antireflective coating (if present), the overlying photoresist (if present), and the lithographic wavelength employed (e.g., ArF, KrF, etc.).

The antireflective coating, if present, can be made of any suitable antireflective material, such as, for example, a low temperature oxide (LTO), SiARC, TiARC, or SiON. The antireflective coating can be deposited using, for example, a spin-on process. The photoresist can include any suitable photoresist material, such as, for example, 248 nm resists, 193 nm resists, 157 nm resists, or EUV (extreme ultraviolet) resists. In some embodiments, the photoresist can be made of a light sensitive polymer, and can be deposited using any suitable resist process, such as spin-on coating.

In some embodiments, a photoresist, if present, can be patterned (opened) by exposure to a photo-lithography developing solvent to expose a surface of an antireflective coating. The pattern in the photoresist can be transferred to the underlying antireflective coating using a dry etch process. The pattern in the antireflective coating can be transferred to an underlying OPL using, for example, a wet etch, a dry etch, or a combination of wet and/or dry etches.

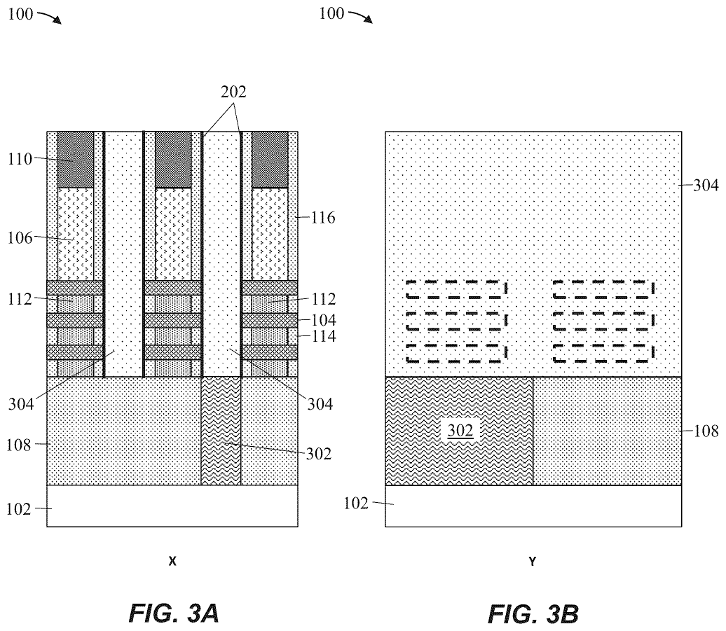

FIGS. 3A and 3B depict cross-sectional views of the semiconductor wafer 100 taken along the lines X and Y, respectively, after additional fabrication operations. As shown in FIGS. 3A and 3B, the patterning film stack 206 is removed and a backside sacrificial region 302 (also referred to as a backside contact placeholder) is formed in the backside contact placeholder trench 204. In some embodiments, the backside sacrificial region 302 is made of a material selected to have etch selectivity with respect to the buried oxide layer 108. For example, in embodiments where the buried oxide layer 108 is a silicon oxide layer, the backside sacrificial region 302 can include silicon germanium, or silicon germanium with a silicon cap (not separately shown). In some embodiments, the backside sacrificial region 302 is epitaxially grown from the substrate 102, although other formation and/or deposition techniques are possible. In some embodiments, the backside sacrificial region 302 is formed and/or deposited to be substantially (within tooling limits) coplanar to the buried oxide layer 108.

In some embodiments, a frontside sacrificial region 304 is formed on the backside contact placeholder trench 204 to fill remaining portions of the backside contact placeholder trench 204 and/or to replace the previously removed patterning film stack 206. While not meant to be particularly limited, the frontside sacrificial region 304 can be made of an OPL material. In some embodiments, the frontside sacrificial region 304 is planarized (via, for example, an etch back) to the hard mask 110.

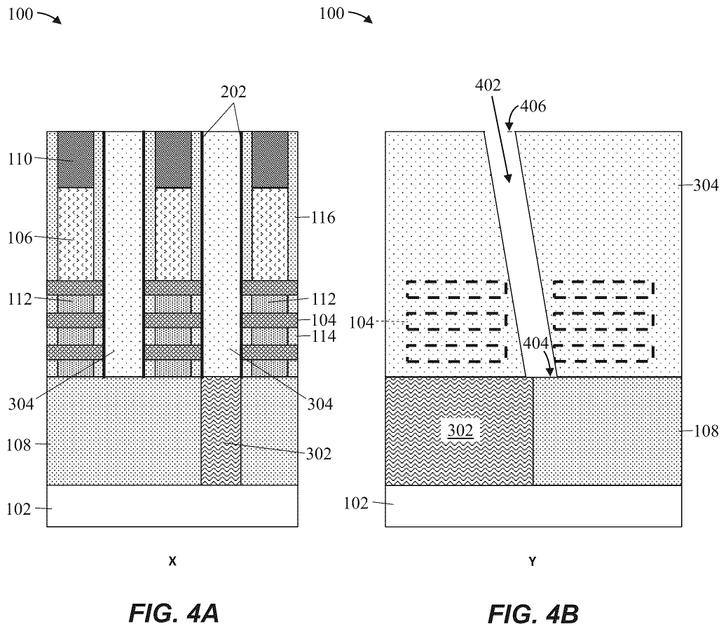

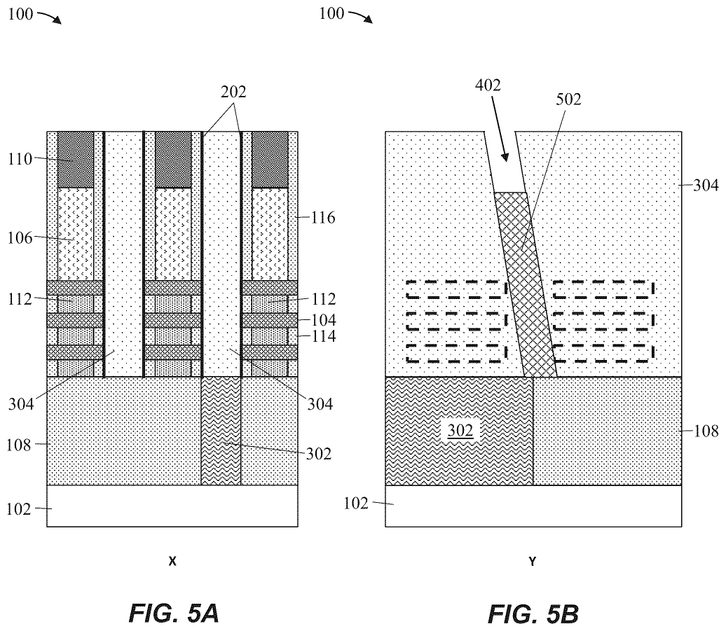

FIGS. 4A and 4B depict cross-sectional views of the semiconductor wafer 100 taken along the lines X and Y, respectively, after additional fabrication operations. As shown in FIGS. 4A and 4B, an angled cut 402 (also referred to as an angled epitaxy cut or as an angled source/drain cut) is formed in the frontside sacrificial region 304. In some embodiments, the angled cut 402 is formed via a directional etch at an angle of between 10 and 45 degrees, for example 30 degrees, although other cut angles are within the contemplated scope of this disclosure. In some embodiments, the angle of the directional etch is selected such that a bottom edge 404 (base) of the angled cut 402 (and the subsequent isolation pillar, refer to FIG. 5B) lands at, or within a predetermined distance (e.g., within 50 nm, 20 nm, 10 nm, etc.) of the interface between the buried oxide layer 108 and the backside sacrificial region 302 and a top edge 404 (opening) of the angled cut 402 (and the subsequent isolation pillar, refer to FIG. 5B) is oriented within a predetermined distance (e.g., within 50 nm, 20 nm, 10 nm, etc.) of the one or more nanosheets 104.

FIGS. 5A and 5B depict cross-sectional views of the semiconductor wafer 100 taken along the lines X and Y, respectively, after additional fabrication operations. As shown in FIGS. 5A and 5B, an angled isolation pillar 502 (also referred to as an angled source/drain isolation pillar and/or as an angled dielectric bar) is formed in the angled cut 402. The angled isolation pillar 502 can be made from any suitable dielectric materials, such as, for example, a low-k dielectric, a nitride, silicon nitride, silicon oxide, SiON, SiC, SiOCN, SiBCN, etc.

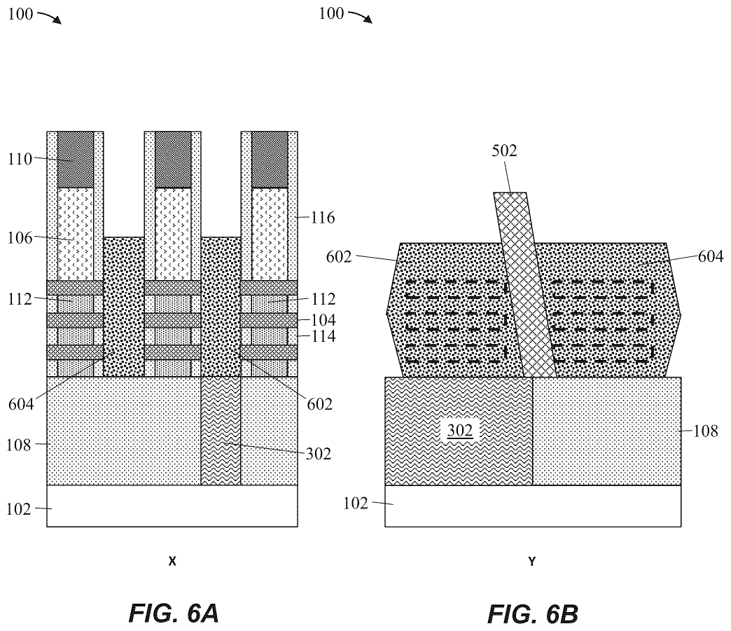

FIGS. 6A and 6B depict cross-sectional views of the semiconductor wafer 100 taken along the lines X and Y, respectively, after additional fabrication operations. As shown in FIGS. 6A and 6B, the frontside sacrificial region 304 and the protective spacers 202 are removed using, for example, a wet etch, a dry etch, or a combination of sequential wet and/or dry etches.

As further shown in FIGS. 6A and 6B, a first source/drain (S/D) region 602 is formed on the backside sacrificial region 302 and a second S/D region 604 is formed opposite the first S/D region 602. Notably, the angled isolation pillar 502 prevents a short between the first S/D region 602 and the second S/D region 604, even for relatively narrow (e.g., sub 20 nm) channel-to-channel spacings.

In some embodiments, the S/D regions 602, 604 can be epitaxially grown using, for example, vapor-phase epitaxy (VPE), molecular beam epitaxy (MBE), liquid-phase epitaxy (LPE), or other suitable processes. The S/D regions 602, 604 can be semiconductor materials epitaxially grown from gaseous or liquid precursors. In some embodiments, the gas source for the epitaxial deposition of semiconductor material includes a silicon containing gas source, a germanium containing gas source, or a combination thereof. For example, a silicon layer can be epitaxially deposited (or grown) from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. A germanium layer can be epitaxially deposited from a germanium gas source that is selected from the group consisting of germane, digermane, halogermane, dichlorogermane, trichlorogermane, tetrachlorogermane and combinations thereof. A silicon germanium alloy layer can be epitaxially formed utilizing a combination of such gas sources. Carrier gases like hydrogen, nitrogen, helium and argon can be used. In some embodiments, the epitaxial semiconductor materials include carbon doped silicon (Si:C). This Si:C layer can be grown in the same chamber used for other epitaxy steps or in a dedicated Si:C epitaxy chamber. The Si:C can include carbon in the range of about 0.2 percent to about 3.0 percent.

Epitaxially grown silicon and silicon germanium can be doped by adding n-type dopants (e.g., P or As) or p-type dopants (e.g., Ga, B, BF₂, or Al) as desired. In some embodiments, the S/D regions 602, 604 can be epitaxially formed and doped by a variety of methods, such as, for example, in-situ doped epitaxy (doped during deposition), doped following the epitaxy, or by implantation and plasma doping. The dopant concentration in the doped regions can range from 1×10¹⁹ cm⁻³ to 2×10²¹ cm⁻³, or between 1×10²⁰ cm⁻³ and 1×10²¹ cm⁻³.

FIGS. 7A and 7B depict cross-sectional views of the semiconductor wafer 100 taken along the lines X and Y, respectively, after additional fabrication operations. As shown in FIGS. 7A and 7B, the sacrificial gate(s) 106 can be replaced with a conductive gate(s) 702 (each also referred to as a metal gate, or simply, a gate). The conductive gate 702 can be a high-k metal gate (HKMG) formed over channel regions of the one or more nanosheets 104 using, for example, known replacement metal gate (RMG) processes, or so-called gate-last processes. In some embodiments, the conductive gate 702 can include a gate dielectric and a work function metal stack (not separately depicted).

In some embodiments, the gate dielectric is a high-k dielectric film formed on a surface (sidewall) of the one or more nanosheets 104. The high-k dielectric film can be made of, for example, silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum. In some embodiments, the high-k dielectric film can have a thickness of about 0.5 nm to about 4 nm. In some embodiments, the high-k dielectric film includes hafnium oxide and has a thickness of about 1 nm, although other thicknesses are within the contemplated scope of this disclosure.

The work function metal stack, if present, can include one or more work function layers positioned between the high-k dielectric film and a bulk gate material. In some embodiments, the conductive gate 702 includes one or more work function layers, but does not include a bulk gate material. The work function layers can be made of, for example, aluminum, lanthanum oxide, magnesium oxide, strontium titanate, strontium oxide, titanium nitride, tantalum nitride, hafnium nitride, tungsten nitride, molybdenum nitride, niobium nitride, hafnium silicon nitride, titanium aluminum nitride, tantalum silicon nitride, titanium aluminum carbide, tantalum carbide, and combinations thereof. The work function layers can serve to modify the work function of the conductive gate 702 and enables tuning of the device threshold voltage. The work function layers can be formed to a thickness of about 0.5 to 6 nm, although other thicknesses are within the contemplated scope of this disclosure. In some embodiments, each of the work function layers can be formed to a different thickness.

In some embodiments, the conductive gate 702 includes a main body formed from bulk conductive gate material(s) deposited over the work function layers and/or gate dielectrics. The bulk gate material can include any suitable conducting material, such as, for example, metal (e.g., tungsten, titanium, tantalum, ruthenium, zirconium, cobalt, copper, aluminum, lead, platinum, tin, silver, gold), conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), conductive carbon, graphene, or any suitable combination of these materials. The conductive gate material can further include dopants that are incorporated during or after deposition.

In some embodiments, a dielectric cap 704 is formed over the conductive gate 702. The dielectric cap 704 can be made of any suitable dielectric material, such as, for example, SiN. The dielectric cap 704 is often referred to as a self-aligned cap (SAC cap), as the dielectric cap 704 is confined (that is, self-aligned) between sidewalls of the gate spacers 116.

In some embodiments, an interlayer dielectric (ILD) 706 (sometimes referred to as a frontside ILD) can be formed over the semiconductor wafer 100. In some embodiments, the semiconductor wafer 100 can be planarized using, for example, chemical-mechanical planarization (CMP), to a surface of the dielectric cap 704.

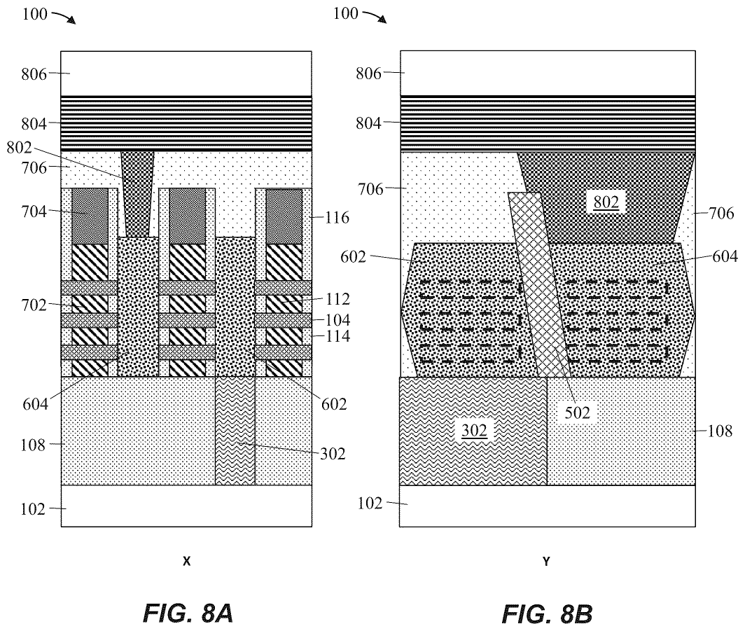

FIGS. 8A and 8B depict cross-sectional views of the semiconductor wafer 100 taken along the lines X and Y, respectively, after additional fabrication operations. As shown in FIGS. 8A and 8B, a contact 802 (also referred to as frontside source/drain contact) can be formed over the substrate 102. In some embodiments, the contact 802 can be formed in or deposited into a contact trench (not separately shown) made in the ILD 706. In some embodiments, additional dielectric material is added to the ILD 706 prior to forming the contact trench and depositing the contact 802.

The contact 802 provides electrical contact between the second S/D region 604 and other structures on the frontside of the semiconductor wafer 100, such as a frontside interconnect 804 (sometimes referred to as a BEOL interconnect). Similarly, additional frontside contacts (not separately shown) can be formed in or deposited into contact trenches to make electrical contact with the conductive gate 702. The frontside interconnect 804 can be, or include, a frontside power delivery network (PDN). The frontside interconnect 804 and/or PDN can include any number of conductive/metal layers, lines, and vias, as desired, and can be formed using known BEOL interconnect fabrication processes.

The contact 802 can be formed from conductive materials that include a silicide (not separately shown) being formed between contact 802 and the second S/D region 604. In some embodiments, a silicide liner, such as, for example, Ti, Ni, NiPt, etc., is deposited over the second S/D region 604 as well as, optionally, an additional metal adhesion layer such as TiN, TaN, etc., and conductive metals, such as W, Ru, Co, Mo and copper. Notably, the angled isolation pillar 502 maximizes contact area between the second S/D region 604 and the contact 802, reducing contact resistance by forming a larger silicide area.

In some embodiments, a carrier wafer 806 is formed over the BEOL structures (e.g., the frontside interconnect 804). The carrier wafer 806 can be made of a same or different material as the substrate 102, such as silicon, silicon germanium, and/or a wafer handling material.

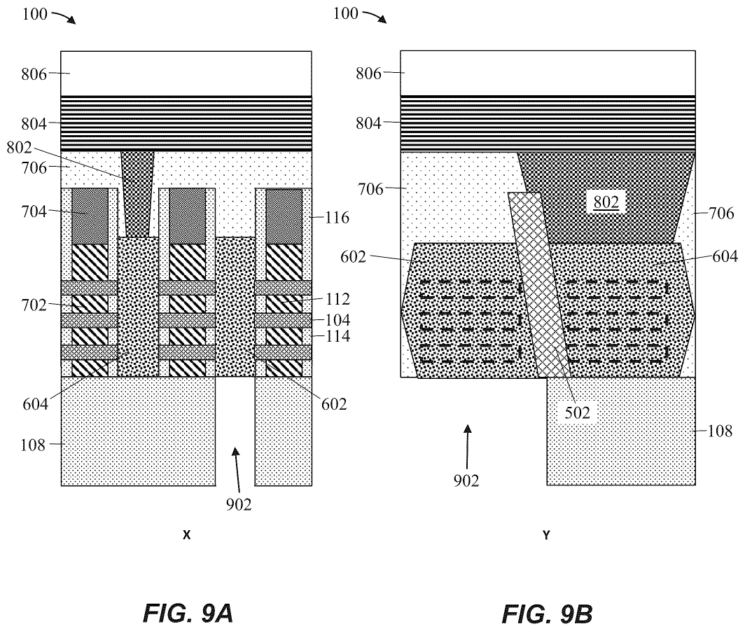

FIGS. 9A and 9B depict cross-sectional views of the semiconductor wafer 100 taken along the lines X and Y, respectively, after additional fabrication operations. As shown in FIGS. 9A and 9B, the semiconductor wafer 100 is flipped and the substrate 102 is removed post-wafer flip. In some embodiments, removal of the substrate 102 lands (or stops) on the buried oxide layer 108. For example, the substrate 102 can be removed by grinding and/or CMP, followed by dry etch and wet etch processes to remove substrate 102 (e.g., silicon), stopping on the buried oxide layer 108. Note that the orientation of the semiconductor wafer 100 shown in FIGS. 9A and 9B remains fixed for ease of discussion.

As further shown in FIGS. 9A and 9B, the backside sacrificial region 302 is removed after stripping off the substrate 132, defining a backside contact trench 902. In some embodiments, the backside sacrificial region 302 is removed using a wet and/or dry etch that stops on the first S/D region 602.

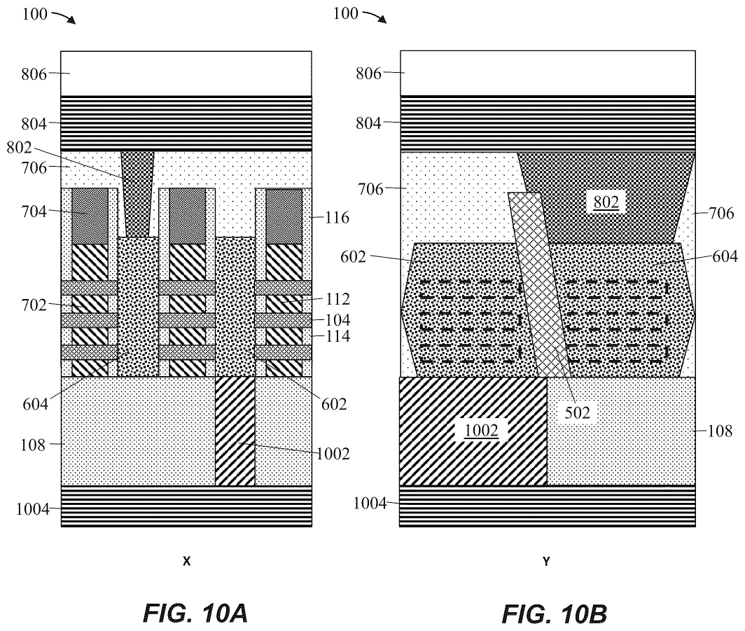

FIGS. 10A and 10B depict cross-sectional views of the semiconductor wafer 100 taken along the lines X and Y, respectively, after additional fabrication operations. As shown in FIGS. 10A and 10B, a contact 1002 (also referred to as a backside source/drain contact) can be formed in the backside contact trench 902. The contact 1002 can be formed of similar conductive materials as the contact 802 discussed previously. Advantageously, due to the angled shape of the angled isolation pillar 502, the backside contact area between the contact 1002 and the first S/D region 602 is maximized.

The contact 1002 provides electrical contact between the first S/D region 602 and other structures on the backside of the semiconductor wafer 100, such as a backside interconnect 1004. Similarly, additional backside contacts (not separately shown) can be formed in or deposited into contact trenches to make electrical contact with the conductive gate 702. The backside interconnect 1004 can be, or include, a backside power delivery network (BSPDN). The backside interconnect 1004 and/or BSPDN can include any number of conductive/metal layers, lines, and vias, and can be formed in a similar manner as the BEOL interconnect structures (e.g., frontside interconnect 804) discussed previously, except that the backside interconnect 1004 is formed on an opposite side of the semiconductor wafer 100. Additional backside layers and dielectrics (omitted for clarity) can be formed before or after the backside interconnect 1004 and/or backside interconnect 1004.

After backside processing is complete, the semiconductor wafer 100 can be finalized using known processes (e.g., additional BEOL, far back end of line (FBEOL), and packaging processes used to define a final device, including the incorporation of additional frontside and/or backside metallization layers).

FIG. 11 depicts a cross-sectional view of the semiconductor wafer 100 taken along the line Y after the processing operation shown in FIG. 10B. Observe, from FIG. 11, that a first frontside contact size W1′ at the interface between the second S/D region 604 and the contact 802 is longer than a second frontside contact size W1 over the first S/D region 602 as a result of the angled isolation pillar 502. Notably, the relatively shorter second frontside contact size W1 over the first S/D region 602 is immaterial, as electrical contact to the first S/D region 602 occurs from the backside.

Similarly, observe that a first backside contact size W2′ at the interface between the first S/D region 602 and the contact 1002 is longer than a second backside contact size W2 below the second S/D region 604 as a result of the angled isolation pillar 502. Notably, the relatively shorter second backside contact size W2 below the second S/D region 604 is immaterial, as electrical contact to the second S/D region 604 occurs from the frontside.

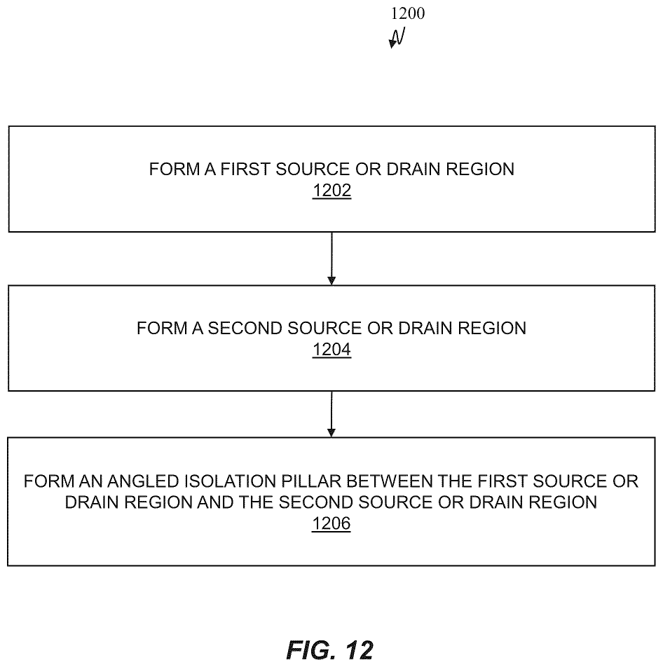

FIG. 12 depicts a flow diagram illustrating a method 1200 that leverages an angled epitaxy cut to provide an angled source/drain isolation pillar that optimizes contact size for both frontside contacts and backside contacts according to one or more embodiments of the disclosure. The method 1200 is described in reference to FIGS. 1A-11 and may include additional blocks not depicted in FIG. 12. Although depicted in a particular order, the blocks depicted in FIG. 12 can be rearranged, subdivided, and/or combined.

As block 1202, the method includes forming a first S/D region. At block 1204, the method includes forming a second S/D region. In some embodiments, the method includes forming a frontside contact on the second S/D region and forming a backside contact on the first S/D region.

At block 1206, the method includes forming an angled isolation pillar between the first S/D region and the second S/D region. In some embodiments, a first frontside contact size at an interface between the second S/D region and the frontside contact is longer than a second frontside contact size over the first S/D region and opposite the backside contact, and a first backside contact size at an interface between the first S/D region and the backside contact is longer than a second backside contact size below the second S/D region and opposite the frontside contact.

In some embodiments, the first S/D region is electrically coupled to a backside of the semiconductor device through the backside contact and the second S/D region is electrically coupled to a frontside of the semiconductor device through the frontside contact. In some embodiments, the first S/D region is not electrically coupled to the a frontside of the semiconductor device and the second S/D region is not electrically coupled to a backside of the semiconductor device.

In some embodiments, the method includes forming a nanosheet stack having one or more nanosheets in direct contact with the first S/D region and the second S/D region. In some embodiments, a width of the backside contact is greater than a width of the one or more nanosheets.

In some embodiments, the method includes forming a frontside interconnect on the frontside contact and forming a backside interconnect on the backside contact.

In some embodiments, the method includes forming a backside sacrificial region on the first S/D region and replacing the backside sacrificial region with the backside contact.

In some embodiments, the method includes forming protective spacers on sidewalls of the one or more nanosheets and forming a frontside sacrificial region on the backside sacrificial region.

In some embodiments, the method includes forming an angled cut in the frontside sacrificial region. In some embodiments, forming the angled isolation pillar includes filling a portion of the angled cut with dielectric material.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the disclosure of the disclosure, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device comprising:
a first source or drain (S/D) region;
a second S/D region; and
an angled isolation pillar between the first S/D region and the second S/D region.

2. The semiconductor device of claim 1, further comprising:
a frontside contact on the second S/D region; and
a backside contact on the first S/D region.

3. The semiconductor device of claim 2, wherein a first frontside contact size at an interface between the second S/D region and the frontside contact is longer than a second frontside contact size over the first S/D region and opposite the backside contact, and a first backside contact size at an interface between the first S/D region and the backside contact is longer than a second backside contact size below the second S/D region and opposite the frontside contact.

4. The semiconductor device of claim 2, wherein the first S/D region is electrically coupled to a backside of the semiconductor device through the backside contact and the second S/D region is electrically coupled to a frontside of the semiconductor device through the frontside contact.

5. The semiconductor device of claim 4, wherein the first S/D region is not electrically coupled to the frontside of the semiconductor device and the second S/D region is not electrically coupled to the backside of the semiconductor device.

6. The semiconductor device of claim 2, further comprising a nanosheet stack comprising one or more nanosheets in direct contact with the first S/D region and the second S/D region.

7. The semiconductor device of claim 6, wherein a width of the backside contact is greater than a width of the one or more nanosheets.

8. The semiconductor device of claim 2, further comprising:
a frontside interconnect on the frontside contact; and
a backside interconnect on the backside contact.

9. A method for forming a semiconductor device, the method comprising:
forming a first source or drain (S/D) region;
forming a second S/D region; and
forming an angled isolation pillar between the first S/D region and the second S/D region.

10. The method of claim 9, further comprising:
forming a frontside contact on the second S/D region; and
forming a backside contact on the first S/D region.

11. The method of claim 10, wherein a first frontside contact size at an interface between the second S/D region and the frontside contact is longer than a second frontside contact size over the first S/D region and opposite the backside contact, and a first backside contact size at an interface between the first S/D region and the backside contact is longer than a second backside contact size below the second S/D region and opposite the frontside contact.

12. The method of claim 10, wherein the first S/D region is electrically coupled to a backside of the semiconductor device through the backside contact and the second S/D region is electrically coupled to a frontside of the semiconductor device through the frontside contact.

13. The method of claim 12, wherein the first S/D region is not electrically coupled to the frontside of the semiconductor device and the second S/D region is not electrically coupled to the backside of the semiconductor device.

14. The method of claim 10, further comprising forming a nanosheet stack comprising one or more nanosheets in direct contact with the first S/D region and the second S/D region.

15. The method of claim 14, wherein a width of the backside contact is greater than a width of the one or more nanosheets.

16. The method of claim 10, further comprising:
forming a frontside interconnect on the frontside contact; and
forming a backside interconnect on the backside contact.

17. The method of claim 14, further comprising:
forming a backside sacrificial region on the first S/D region; and
replacing the backside sacrificial region with the backside contact.

18. The method of claim 17, further comprising:
forming protective spacers on sidewalls of the one or more nanosheets; and
forming a frontside sacrificial region on the backside sacrificial region.

19. The method of claim 18, further comprising forming an angled cut in the frontside sacrificial region.

20. The method of claim 19, wherein forming the angled isolation pillar comprising filling a portion of the angled cut with dielectric material.
